(19) United States
(12) Patent Application Publication
(10) Pub. No.: US 2007/0284652 A1
(43) Pub. Date: Dec. 13, 2007

(54) Semiconductor memory device

(76) Inventors: Takuya Kobayashi, Nagareyama-shi (JP); Katsuyuki Sekine, Yokohama-shi (JP); Yoshio Ozawa, Yokohama-shi (JP); Masayuki Tanaka, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/783,141

(22) Filed: Apr. 6, 2007

(30) Foreign Application Priority Data
May 11, 2006 (JP) 2006-132764

(51) Int. Cl. H01L 29/792

(52) U.S. Cl. 257/324; 257/E29.309

(57) ABSTRACT

A semiconductor memory device capable of suppressing detrapping of stored charges from a charge storage dielectric is disclosed. According to one aspect of the present invention, there is provided a semiconductor memory device comprising a semiconductor substrate, a blocking dielectric disposed on the semiconductor substrate a charge storage dielectric disposed on the blocking dielectric to store holes, a hole conductive dielectric disposed on the charge storage dielectric, and a gate electrode disposed on the hole conductive dielectric.

### CROSS-REFERENCE TO RELATED APPLICATIONS

This application is based upon and claims the benefit of priority from prior Japanese Patent Application No. 2006-132764, filed May 11, 2006, the entire contents of which are incorporated herein by reference.

### BACKGROUND OF THE INVENTION

1. Field of the Invention

The present invention relates to a semiconductor memory device, and more particularly to a nonvolatile semiconductor memory device which has a charge storage dielectric disposed on a semiconductor substrate.

2. Description of the Related Art

With the micronization of a semiconductor device, a dielectric with a high dielectric constant has been demanded for a charge storage dielectric in a nonvolatile semiconductor memory device of a metal-oxide-nitride-oxide-silicon (MONOS) type. However, if the high dielectric constant dielectric is used only in the form of a single layer, there is a problem of large detrapping. Where, the “detrapping” means that charges stored in the charge storage dielectric are discharged to be lost unintentionally.

A semiconductor memory device that solves the detrapping problem is disclosed, for example, in Jpn. Pat. Appln. KOKAI Publication No. 2004-336044. A gate laminated dielectric of the conventional MONOS type semiconductor memory device uses a so-called ONO film constituted of a silicon oxide film (SiO₂ film), a silicon nitride film (Si₃N₄ film), and another SiO₂ film in which the Si₃N₄ film serving as a charge storage dielectric is held between SiO₂ films. On the other hand, the semiconductor memory device disclosed in the above patent application includes an OHA film constituted of a tunneling dielectric, a trapping film, and a diffusion barrier film. Specifically, the tunneling dielectric is an SiO₂ film, the trapping film is a hafnium oxide (HfO₂) film doped with dysprosium (Dy), and the diffusion barrier film is an aluminum oxide (Al₂O₃) film. According to this semiconductor memory device, charges, i.e., electrons, are passed through the tunneling dielectric from a semiconductor substrate to the trapping film, and trapped to be stored in the trapping film. The diffusion barrier film prevents passage of some of the electrons through the trapping film to reach a gate electrode. In the semiconductor memory device, the HfO₂ film is doped with Dy to adjust a trap density, and operation voltages, such as data holding and erasing voltages, are reduced, thereby realizing an erasure operation faster than that of the conventional semiconductor memory device.

However, in the MONOS type semiconductor memory device including the semiconductor memory device disclosed in the patent application above, there is a problem of large detrapping of electrons stored in the charge storage dielectric to store data. Since current flows through the tunneling dielectric during both of writing and erasing data, there is a problem that lifetime of the semiconductor device is determined by the numbers of times of writing and erasing data. Besides, voltages of opposite directions must be applied during writing and erasing data, creating a problem that a peripheral circuit must be provided according to supply both positive and negative voltages.

### BRIEF SUMMARY OF THE INVENTION

According to one aspect of the present invention, there is provided a semiconductor memory device comprising: a semiconductor substrate; a blocking dielectric disposed on the semiconductor substrate: a charge storage dielectric disposed on the blocking dielectric to store holes; a hole conductive dielectric disposed on the charge storage dielectric; and a gate electrode disposed on the hole conductive dielectric.

### BRIEF DESCRIPTION OF THE SEVERAL VIEWS OF THE DRAWINGS

FIG. 1 illustrates an example of a sectional structure of a memory cell transistor of a nonvolatile semiconductor memory device according to an embodiment of the present invention;

FIGS. 2A to 2C are energy band diagrams illustrating operations of the semiconductor memory device of the embodiment; and

FIGS. 3A and 3B are energy band diagrams illustrating operations of a conventional MONOS type semiconductor memory device.

### DETAILED DESCRIPTION OF THE INVENTION

Embodiments of the present invention provide a semiconductor memory device capable of suppressing detrapping of stored charges from a charge storage dielectric.

According to an embodiment of the present invention, a MONOS type nonvolatile semiconductor memory device of storing holes in a charge storage dielectric is provided. By storing the holes, less detrapping of charge is achieved as compared with a conventional MONOS type semiconductor memory device storing electrons as charges. In other words, data retention is facilitated. Moreover, the device can be operated only by applying positive electric fields.

The embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

### Embodiment

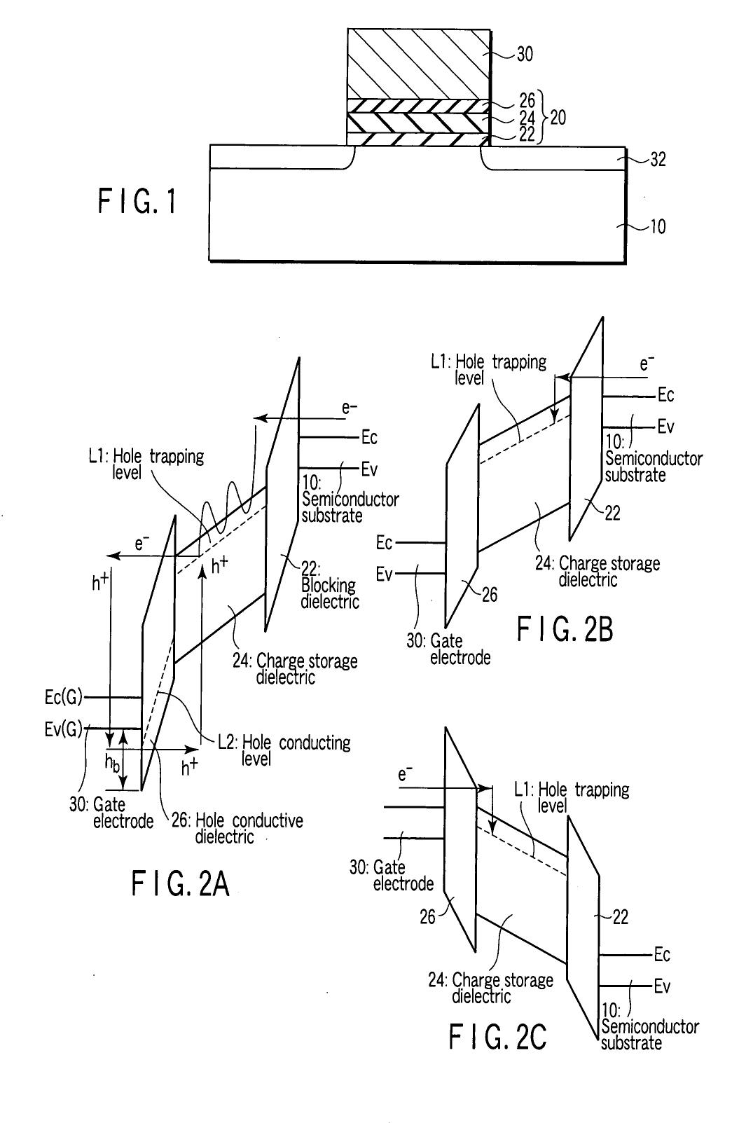

FIG. 1 illustrates an example of a sectional structure of a memory cell transistor of a nonvolatile semiconductor memory device according to an embodiment of the present invention. The nonvolatile semiconductor memory device includes a gate laminated dielectric 20 which includes a blocking dielectric 22, a charge storage dielectric 24 and a hole conductive dielectric 26 between a semiconductor substrate 10 and a control gate electrode 30 disposed thereabove.

The hole conductive dielectric 26 is a dielectric which has an energy level in a band gap for facilitating hole conduction, i.e., a shallow energy level to holes. Through the hole conductive dielectric 26, holes are injected from the control gate electrode 30 into the charge storage dielectric 24. The shallow energy level to holes indicates energy level(s) located between a valence band and a mid-gap (center of the band gap) in the band gap of the hole conductive dielectric 26. For the hole conductive dielectric 26, for example, a dielectric containing nitrogen such as a silicon nitride (Si₃N₄) film or a hafnium silicon oxynitride (HfSiON) film can be used. In the dielectric containing nitrogen, a barrier height to holes between a metal (electrode) and the dielectric is reduced to facilitate hole injection from the electrode.

The charge storage dielectric 24 is a dielectric for storing holes, and has a deep energy level to holes, i.e., a shallow energy level to electrons. The deep energy level to holes indicates energy level(s) located between a conduction band and the midgap in the band gap of the charge storage dielectric 24, and it will also be called a hole trapping level hereinafter. For the charge storage dielectric 24, for example, a dielectric having a high dielectric constant such as a hafnium silicon oxide (HfSiO) film, a hafnium silicon oxynitride (HfSiON) film, a hafnium oxide (HfO₂) film, or a hafnium aluminum oxide (HfAlO) film can be used. Holes are not easily detrapped as the holes injected into the charge storage dielectric 24 are trapped at the hole trapping level.

The blocking dielectric 22 blocks hole movement to prevent from traveling to the semiconductor substrate 10 from the charge storage dielectric 24, where the holes are injected from the gate electrode 30 into the charge storage dielectric 24. For the blocking dielectric 22, for example, an Si₃N₄ film or an SiO₂ film can be used.

A gate laminated dielectric of the conventional MONOS type semiconductor memory device includes a tunneling dielectric, a charge storage dielectric, and a blocking dielectric from a semiconductor substrate side. In contrast, function of each of the dielectrics in the gate laminated dielectric is reversed and upside down in the semiconductor memory device of the present embodiment. Additionally, while electrons are stored in the charge storage dielectric to store data in the conventional semiconductor memory device, holes are stored in the charge storage dielectric to store data according to the embodiment. In this regard, the semiconductor memory device of the embodiment is also different from the conventional semiconductor memory device.

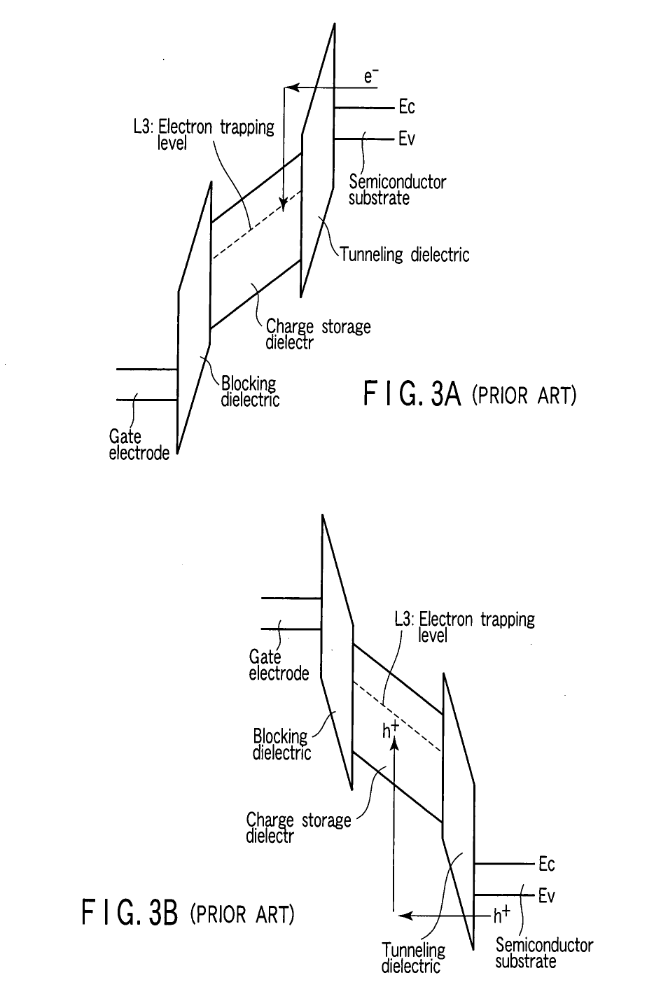

An example of an operation of the semiconductor memory device of the embodiment will be described below. In addition, the operation will be compared with that of the conventional MONOS type semiconductor memory device. FIGS. 2A to 2C are energy band diagrams illustrating operations of the semiconductor memory device of the embodiment. FIG. 2A shows an operation during writing, and FIGS. 2B and 2C show operations during erasing. FIGS. 3A and 3B are energy band diagrams illustrating operations of a conventional MONOS type semiconductor memory device, as references. Each of FIGS. 2A to 2C and FIGS. 3A and 3B shows the semiconductor substrate 10 in the right end, the gate electrode 30 in the left end, and the charge storage dielectric 24 in the center. Two upper and lower lines in the energy band diagram indicate edges of a conduction band Ec and a valence band Ev, respectively, and a gap therebetween is a band gap. Energy levels related to the description of the embodiment are indicated by a broken line in the band gap.

Writing data in the semiconductor memory device of the embodiment is carried out by storing holes in the charge storage dielectric 24. During the writing, a high positive electric field is applied between the gate electrode 30 and the semiconductor substrate 10. Accordingly, as shown in FIG. 2A, the energy band diagram is drawn so that right upward inclination is larger. Electrons (e⁻) in the semiconductor substrate 10 are injected through the blocking dielectric 22 into the charge storage dielectric 24 at a high energy. The charge storage dielectric 24 has a deep energy level L₁ to holes (hole trapping level), that is, a shallow energy level to electrons, as described above. The injected high-energy electrons are hopped via the hole trapping level L1 and/or another shallow energy level to electrons to pass through the charge storage dielectric 24, and then pass through the hole conductive dielectric 26 to reach the gate electrode 30. The high-energy electrons that have reached the gate electrode 30 cause impact ionization in the gate electrode 30 to lose the energy. Through the impact ionization, electron and hole pairs are generated in the gate electrode 30. Generated holes (h⁺) are accumulated in a valance band Ev(G) of the gate electrode 30. The generated electrons contribute to conduction in the gate electrode 30 as they are majority carriers in the gate electrode 30. Since the hole conductive dielectric 26 has a low barrier height h_{b} to holes with respect to the valence band Ev(G) of the gate electrode 30, the holes are injected from the gate electrode 30 into the hole conductive dielectric 26. As the hole conductive dielectric 26 has a hole conducting level L₂, the holes injected into the hole conductive dielectric 26 reach the charge storage dielectric 24 via the hole conducting level L₂. The holes that have reached the charge storage dielectric 24 are trapped at the hole trapping level L₁. If energy of the holes reaching the charge storage dielectric 24 is high, there is a possibility that the holes will pass through the charge storage dielectric 24 to reach the semiconductor substrate 10. However, movement of the holes will be blocked by the blocking dielectric 22. Accordingly, the holes can be stored in the charge storage dielectric 24 to enable writing data. As the hole trapping level L₁ is a deep energy level to holes, a probability that the holes will be detrapped is low. Thus, it can be improved data retention characteristics of the semiconductor memory device.

Erasing data in the semiconductor memory device of the embodiment is carried out by injecting electrons into the charge storage dielectric 24 to recombine them with the stored holes, thereby extinguishing the holes. There are two methods for injecting electrons. One is a method for injecting electrons by applying a intermediate positive electric field between the gate electrode 30 and the semiconductor substrate 10 as shown in FIG. 2B. The other is a method for injecting electrons by applying an intermediate negative electric field between the gate electrode 30 and the semiconductor substrate 10, which is opposite to the above.

Referring to FIG. 2B, the case of erasing data by applying the intermediate positive electric field between the gate electrode 30 and the semiconductor substrate 10 to inject electrons from the semiconductor substrate 10 will be described. As the applied electric field is lower than that during the writing, right upward inclination of the energy band diagram is smaller. Electrons are injected from the semiconductor substrate 10 through the blocking dielectric 22 into the charge storage dielectric 24. However, as the applied electric field is lower than that during the writing, energy of the injected electrons is also lowered. Further, as there are holes trapped at the hole trapping level L₁ of the charge storage dielectric 24, the injected electrons are recombined with the trapped holes to extinguish the holes in place of being hopped to pass via the hole trapping level L₁.

According to the embodiment of the aforementioned operation, writing and erasing data can be carried out only by changing an electric field applied between the gate electrode 30 and the semiconductor substrate 10 during writing and erasing, i.e., applying an electric field of one-direction (positive) different in strength. It is different from the case of the conventional MONOS type semiconductor memory device in which electric fields of opposite directions must be applied during writing and erasing data. Accordingly, since it can be operated the semiconductor memory device only by applying the electric field of one-direction, peripheral circuits can be simplified as compared with the conventional device.

Next, referring to FIG. 2C, a case of erasing data by injecting electrons from the gate electrode 30 into the charge storage dielectric 24 will be described. In this case, an intermediate negative electric field opposite to the above is applied between the gate electrode 30 and the semiconductor substrate 10. In an energy band diagram, this operation is indicated by right downward inclination reverse to that of FIG. 2B. Electrons are injected from the gate electrode 30 into the charge storage dielectric 24 through the hole conductive dielectric 26. As in the case of FIG. 2B, the injected electrons are recombined with the holes trapped at the hole trapping level L₁ to extinguish the holes in place of being hopped to pass via the hole trapping level L₁ of the charge storage dielectric 24. In this case, no current flows through the blocking dielectric 22 disposed on the semiconductor substrate 10 during erasure. Accordingly, as a current flowing through the blocking dielectric 22 can be halved only during writing, it can be prolonged a lifetime of the semiconductor memory device.

Thus, data can be erased by injecting electrons into the charge storage dielectric 24 to extinguish the stored holes.

An operation electric field of the semiconductor memory device of the embodiment varies depending on device design. For example, the high electric field during writing data is +8 MV/cm to 15 MV/cm, and the electric field during erasing data is a positive or negative electric field of about ½ to ⅔ times of the absolute electric field during writing data.

Next, the operation will be compared with that of the conventional MONOS type semiconductor memory device. According to the conventional semiconductor memory device, as shown in FIG. 3A, during writing data, a high positive electric field is applied between the gate electrode and the semiconductor substrate, as in the case of the embodiment, however, electrons are stored in the charge storage dielectric to store data instead of holes. Electrons are injected from the semiconductor substrate into the charge storage dielectric through the tunneling dielectric. The injected electros are trapped at an electron trapping level L₃ of the charge storage dielectric. Since the electron trapping level L₃ is closer to the midgap than the hole trapping level L₁, the electrons rarely hopped via the electron trapping level L₃. Moreover, even if there are electrons with high-energy, the electrons are blocked by the blocking dielectric disposed between the charge storage dielectric and the gate electrode so that the electrons do not reach to the gate electrode.

During erasing data in the conventional semiconductor memory device, as shown in FIG. 3B, data is erased by applying a high negative electric field between the gate electrode and the semiconductor substrate to inject holes from the semiconductor substrate into the charge storage dielectric thereby extinguishing stored electrons from the charge storage dielectric.

As apparent, the semiconductor memory device of the embodiment of the present invention is different from the conventional semiconductor memory device not only in structure but also in operation. That is, according to the semiconductor memory device of the embodiment, the charges stored in the charge storage dielectric are holes (positive charges), the holes are injected from the gate electrode to the charge storage dielectric by applying the high positive electric field, the holes are extinguished by applying the intermediate positive electric field to inject electrons from the semiconductor substrate to the charge storage dielectric, or by applying the intermediate negative electric field to inject electrons from the gate electrode to the charge storage dielectric, and the like.

Next, a method for manufacturing the semiconductor memory device according to the embodiment of the present invention will be described by referring to a sectional diagram of the memory cell transistor shown in FIG. 1.

In a semiconductor substrate 10, for example, a silicon substrate, an isolation (not shown) is formed by, e.g., shallow trench isolation. A blocking dielectric 22 is deposited on the semiconductor substrate 10 having the isolation formed therein. The blocking dielectric 22 has a function of preventing holes injected into a charge storage dielectric to be formed thereon from flowing-out to the semiconductor substrate 10. For the blocking dielectric 22, for example, an Si₃N₄ film formed by atomic layer deposition (ALD) or chemical vapor deposition (CVD) or an SiO₂ film formed by thermal oxidation or the like can be used. If the Si₃N₄ film is used for the blocking dielectric 22, the film can be formed by a method other than the above, e.g., plasma nitridation of the silicon substrate, or thermal nitridation of the silicon substrate 10 by a heat treatment in an ammonia containing atmosphere. A thickness of the blocking dielectric 22 is, e.g., 3 to 6 nm.

A charge storage dielectric 24 is deposited on the blocking dielectric 22. The charge storage dielectric 24 is a dielectric having a hole trapping level, and traps injected holes to store charges. The charge storage dielectric 24 is preferably to have a higher dielectric constant. As long as it has the above hole trapping level, a dielectric having a dielectric constant higher than that of an Si₃N₄ film can be used. For the charge storage dielectric 24, for example, an HfSiO film formed by metal organic CVD (MOCVD) can be used. In this case, as a source gas, for example, tetradimethyl amino silicon and tetradimethyl amino hafnium can be used. In addition to the above forming methods, e.g., CVD, ALD, sputtering or the like can be used. Further, in addition to the above films, e.g., an HfSiON film, an HfO₂ film, an HfAlO film or the like can be used. A thickness of the charge storage dielectric 24 is, e.g., 3 to 10 nm. After the deposition of the charge storage dielectric 24, it can be heat treated in an oxidizing atmosphere to improve the film quality.

A hole conductive dielectric 26 is formed on the charge storage dielectric 24. The hole conductive dielectric 26 is a dielectric having a shallow energy level to holes. For the hole conductive dielectric 26, for example, an Si₃N₄ film formed by ALD or CVD can be used. A thickness of the hole conductive dielectric 26 is preferably thinner than that of the blocking dielectric 22. In addition to the above Si₃N₄ film, a dielectric containing nitrogen (N) such as an HfSiON film can be used. The dielectric containing nitrogen generally has a shallow energy level to holes, and a low barrier height to holes with respect to a metal (gate electrode). A thickness of the hole conductive dielectric 26 is, e.g., 3 to 6 nm.

Thus, a gate laminated dielectric 20 can be formed.

A conductive film 30 is deposited on the hole conductive dielectric 26. For the conductive film 30, for example, polysilicon doped with a dopant such as phosphorus (P) can be used.

The conductive film 30, the hole conductive dielectric 26, the charge storage dielectric 24, and the blocking dielectric 22 are patterned by lithography and etching. Accordingly, the gate electrode 30 shown in FIG. 1 can be formed.

Then, using the gate electrode 30 as a mask, ions of a dopant such as arsenic (As) are implanted into the semiconductor substrate 10 to form a source/drain 32.

Thus, the memory cell transistor of the semiconductor memory device shown in FIG. 1 can be formed.

Subsequently, the semiconductor memory device of the embodiment is completed through steps necessary for the semiconductor memory device, such as formation of an interlevel dielectric, formation of a multilevel wiring, and the like.

If the charge storage dielectric is thickly formed, then a detrapping probability of the charge storage dielectric itself increases. Therefore, a thickness of the charge storage dielectric is preferably 3 times or less as much as that of the hole conductive dielectric or the blocking dielectric.

The aforementioned embodiment is in no way limitative of the present invention, but various changes and modifications can be made without departing from its scope. For example, the embodiment has been described by way of case of the silicon substrate as the semiconductor substrate. However, in addition to the above semiconductor substrate, a silicon-on-insulator (SOI) substrate can be used, for example.

As described above, according to the embodiment of the present invention, the MONOS type nonvolatile semiconductor memory device in which holes are trapped in the charge storage dielectric to store data can be provided. The semiconductor memory device has many features different from those of the conventional MONOS type semiconductor memory device. The semiconductor memory device is different from the conventional semiconductor memory device in that the holes are stored to store data as described above while the electrons are stored in the conventional device. In structure, the gate laminated dielectric for storing data includes the blocking dielectric, the charge storage dielectric and the hole conductive dielectric from the semiconductor substrate side, and the functions of the dielectrics are reversed and upside down to those of the conventional device. It is also different in storing the data, in the present semiconductor memory device, holes are injected from the gate electrode to the charge storage dielectric by applying the high positive electric field, while in the conventional device, electrons are injected from the semiconductor substrate into the charge storage dielectric. Erasure of stored data can be carried out by injecting electrons from either one of two directions, i.e., injecting electrons from the semiconductor substrate by applying the intermediate positive electric field or injecting electrons from the gate electrode by applying the intermediate negative electric field. It is different from the conventional semiconductor memory device in which holes are injected from one direction, i.e., from the semiconductor substrate to erase data. The semiconductor memory device has an additional feature that detrapping of the holes is rare to occur since the injected holes are trapped at the deep hole trapping level in the charge storage dielectric to store data. As a result, it can be improved data retention characteristics of the semiconductor memory device. Moreover, writing and erasing data can be carried out only by applying the positive electric field with different electric field as described above, thus it is different from the conventional semiconductor memory device in this point. Accordingly, the peripheral circuits can be simplified. Another advantage is that when the erasure method of injecting electrons from the gate electrode is used, a current flowing through the blocking dielectric formed on the semiconductor substrate can be limited to during writing data, and thus it can be prolonged the lifetime of the semiconductor memory device.

Therefore, the present invention can provide the semiconductor memory device which has the aforementioned features and suppresses detrapping of stored charges from the charge storage dielectric.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a semiconductor substrate;
a blocking dielectric disposed on the semiconductor substrate:
a charge storage dielectric disposed on the blocking dielectric to store holes;
a hole conductive dielectric disposed on the charge storage dielectric; and
a gate electrode disposed on the hole conductive dielectric.

2. The semiconductor memory device according to claim 1, wherein the charge storage dielectric has a deep energy level to holes.

3. The semiconductor memory device according to claim 2, wherein the charge storage dielectric is one selected from a hafnium silicon oxide film, a hafnium silicon oxynitride film, a hafnium oxide film, and a hafnium aluminum oxide film.

4. The semiconductor memory device according to claim 2, wherein the hole conductive dielectric has a shallow energy level to holes.

5. The semiconductor memory device according to claim 4, wherein the hole conductive dielectric is a dielectric having a low barrier height to holes with respect to the gate electrode.

6. The semiconductor memory device according to claim 4, wherein the hole conductive dielectric is a dielectric containing nitrogen.

7. The semiconductor memory device according to claim 4, wherein the holes are injected from the gate electrode through the hole conductive dielectric into the charge storage dielectric to be stored therein.

8. The semiconductor memory device according to claim 7, wherein the holes stored in the charge storage dielectric are extinguished by recombining with electrons injected from the gate electrode.

9. The semiconductor memory device according to claim 7, wherein the holes stored in the charge storage dielectric are extinguished by recombining with electrons injected from the semiconductor substrate.

10. The semiconductor memory device according to claim 1, wherein the hole conductive dielectric has a shallow energy level to holes.

11. The semiconductor memory device according to claim 10, wherein the hole conductive dielectric is a dielectric containing nitrogen.

12. The semiconductor memory device according to claim 11, wherein the hole conductive dielectric is a silicon nitride film or a hafnium silicon oxynitride film.

13. The semiconductor memory device according to claim 1, wherein the holes are injected from the gate electrode through the hole conductive dielectric into the charge storage dielectric to be stored therein.

14. The semiconductor memory device according to claim 13, wherein the injection of the holes from the gate electrode into the charge storage dielectric is executed by applying a positive electric field between the gate electrode and the semiconductor substrate.

15. The semiconductor memory device according to claim 14, wherein the positive electric field is 8 MV/cm to 15 MV/cm.

16. The semiconductor memory device according to claim 14, wherein the holes stored in the charge storage dielectric are extinguished by recombining with electrons injected from the gate electrode.

17. The semiconductor memory device according to claim 16, wherein the injection of the electrons from the gate electrode into the charge storage dielectric is executed by applying a negative electric field of ½ to ⅔ of an absolute strength of the hole injection positive electric field between the gate electrode and the semiconductor substrate.

18. The semiconductor memory device according to claim 14, wherein the holes stored in the charge storage dielectric are extinguished by recombining with electrons injected from the semiconductor substrate.

19. The semiconductor memory device according to claim 18, wherein the injection of the electrons from the semiconductor substrate into the charge storage dielectric is executed by applying a positive electric field of ½ to ⅔ of the hole injection positive electric field between the gate electrode and the semiconductor substrate.

20. The semiconductor memory device according to claim 1, wherein a thickness of the charge storage dielectric is 3 times or less as much as that of the hole conductive dielectric.
